(19) United States
(12) Patent Application Publication
(10) Pub. No.: US 2019/0127573 A1
(43) Pub. Date: May 2, 2019

(54) POLYLACTIC ACID RESIN COMPOSITION AND APPLICATION THEREOF

(71) Applicant: Advanced Semiconductor Engineering, Inc., Kaohsiung (TW)

(72) Inventors: Chean-Cheng SU, Kaohsiung (TW); Chih-Pin HUNG, Kaohsiung (TW); Shin-Luh TARNG, Kaohsiung (TW); Chaung Chi WANG, Kaohsiung (TW); Chao Ming TSENG, Kaohsiung (TW); Shiu-Chih WANG, Kaohsiung (TW)

(73) Assignee: Advanced Semiconductor Engineering, Inc., Kaohsiung (TW)

(21) Appl. No.: 15/801,116

(22) Filed: Nov. 1, 2017

(51) Int. Cl. C08L 67/04; H01L 21/673; C08K 5/00; C08K 5/09; C08K 3/36; C08K 3/04; C08K 5/5419

(52) U.S. Cl. CPC C08L 67/04; H01L 21/67336; C08K 5/0083; C08K 5/0025; B29C 45/0001; C08K 3/36; C08K 3/046; C08K 5/5419; C08L 2201/06; C08K 5/09

(57) ABSTRACT

A polylactic acid resin composition includes about 100 parts by weight of a polylactic acid resin, about 0.001 to about 3 parts by weight of a nucleating agent and about 3 to about 70 parts by weight of a filler. The polylactic acid resin composition can be processed into a biodegradable molded article or other product having a high impact strength and a high heat deflection temperature.

### TECHNICAL FIELD

The present disclosure relates to a biodegradable polylactic acid resin composition and its applications.

### DESCRIPTION OF THE RELATED ART

In recent years, plastics formed from natural plants as a raw material have been receiving attention in view of the global warming issue. Polylactic acid (PLA) resin is an environmentally friendly polymer because it is biodegradable and can be derived from renewable resources, such as corn starch. However, PLA resin is recognized for its poor physical properties, such as: low thermal resistance, poor surface resistivity and poor mechanical properties. On the other hand, PLA resin shows a low crystallization rate and a low degree of crystallization so that products formed from PLA may not have sufficient heat deflection temperature (HDT) and impact strength. It is therefore difficult to make use of a PLA resin in electronic applications, such as an integrated circuit (IC) tray. It is desirable to improve the properties of the PLA to expand the application of PLA to the IC field.

IC trays are used for holding, handling, and transporting IC packages. For a suitable IC tray to be used in a manufacturing process, for example, reflow, and shipment of an IC, several specific properties are desired, for example, HDT, impact strength and surface resistivity, among others. At present, there remains a demand for an environmentally friendly IC tray having the properties as desired. A typical IC tray is mainly formed of polyphenylene ether (PPE), which is a petrochemical product and is non-biodegradable in the normal environment. The PPE-based IC tray can release greenhouse gases after burning and cause damage to the environment. There is a need for an environmentally friendly IC tray that has high HDT, high impact strength and low surface resistivity.

### SUMMARY

In some embodiments, the present disclosure provides a polylactic acid (PLA) resin composition including about 100 parts by weight of a PLA resin, about 0.001 to about 3 parts by weight of a nucleating agent based on about 100 parts by weight of the PLA resin, and about 3 to about 70 parts or about 3 to about 50 parts by weight of a filler based on about 100 parts by weight of the PLA resin. The present disclosure also provides a tray for electronics formed from the resin composition of some embodiments of the disclosure. The present disclosure further provides a biodegradable molded article formed from the resin composition of some embodiments of the disclosure.

In some embodiments, the present disclosure further provides a tray for electronics. The tray for electronics includes about 100 parts by weight of a PLA resin, about 0.001 to about 3 parts by weight of a nucleating agent based on about 100 parts by weight of the PLA resin, and about 3 to about 70 parts or about 3 to about 50 parts by weight of a filler based on about 100 parts by weight of the PLA resin.

In some embodiments, the present disclosure also provides a biodegradable molded article. The biodegradable molded article includes about 100 parts by weight of a PLA resin, about 0.001 to about 3 parts by weight of a nucleating agent based on about 100 parts by weight of the PLA resin, and about 3 to about 70 parts or about 3 to about 50 parts by weight of a filler based on about 100 parts by weight of the PLA resin.

### DETAILED DESCRIPTION

### [Polylactic Acid]

In some embodiments of the present disclosure, the polylactic acid (PLA) can be a homopolymer of lactic acid. Optical isomers, namely L-lactic acid (L-form) and D-lactic acid (D-form), exist for lactic acid. For some embodiments of the present disclosure, the PLA may be prepared from a single one of the optical isomers or both of the isomers. For the purpose of reaching a high melting temperature (Tₘ) and a high glass-transition temperature (T_{g}) of the PLA, it is desirable to use of one of the optical isomers as a main component. For example, the content of the L-form of lactic acid may be no less than about 80 mol. % or no more than about 20 mol. % in the PLA; such as where the content of the L-form of lactic acid may be no less than about 85 mol. % or no more than about 16 mol. % in the PLA; or such as where the content of the L-form of lactic acid may be no less than about 90 mol. % or no more than about 12 mol. % in the PLA, with a remainder corresponding to, or including, the D-form of lactic acid.

In other embodiments of the present disclosure, the PLA can be a copolymer of lactic acid and a hydroxycarboxylic acid component other than lactic acid. The hydroxycarboxylic acid component other than lactic acid can be, for example, glycolic acid, hydroxybutyric acid, hydroxyvaleric acid, hydroxypentanoic acid, hydroxycaproic acid, or hydroxyheptanoic acid.

The PLA can be formed by polycondensation methods using the above mentioned monomers or formed by ring-opening polymerization method using corresponding cyclic dimers or compounds of the above mentioned monomers (for example, lactide, which is a cyclic dimer of lactic acid).

A weight average molecular weight (Mw) of the PLA in some embodiments of the present disclosure may be at least any of the following: about 10,000 g/mol, about 20,000 g/mol, about 30,000 g/mol, about 40,000 g/mol and about 50,000 g/mol; and may be at most any of the following: about 160,000 g/mol, about 200,000 g/mol, about 250,000 g/mol, about 300,000 g/mol, about 400,000 g/mol and about 500,000 g/mol. For example, the weight average molecular weight of the PLA may be from about 30,000 g/mol to about 250,000 g/mol.

### [Nucleating Agent]

In some embodiments, the nucleating agent can be employed to improve the arrangement of a nucleus of a crystal of the PLA and enhance the crystallization rate and the degree of crystallization of the PLA. The enhanced crystallizing rate and degree of crystallization of the PLA can contribute to the increase of HDT and impact strength. The nucleating agent, which can enhance the crystallization rate and the degree of crystallization of the PLA, can be used in a resin composition of some embodiments of the present disclosure. In some embodiments, the nucleating agent comprises a metal carbonate (e.g., an alkaline earth metal carbonate such as calcium carbonate or barium carbonate), an ester derivative of citric acid (e.g., acetyl tributyl citrate), a metal silicate (e.g., a hydrated magnesium silicate such as talc), an amino acid (e.g., glycine or L-alanine), a poly(amino acid) (e.g., polyglycine), a heterocyclic organic compound (e.g., N-aminophthalimide), a metal oxide (e.g., titanium dioxide), or a combination of two or more thereof. In some embodiments, the nucleating agent is L-alanine.

The nucleating agent is added to the PLA resin composition of some embodiments of the present disclosure in an amount of about 0.001 to about 3 parts by weight based on about 100 parts by weight of the PLA resin; for example, about 0.001, about 0.005, about 0.01, about 0.05, about 0.1, about 0.5, about 1, about 1.5, about 2, or about 3 parts by weight based on about 100 parts by weight of the PLA resin.

### [Filler]

Fillers can be added to a resin composition for a variety of purposes, such as reducing cost, improving mechanical strength, or modifying the appearance of a final product. Different fillers are chosen for different purposes. It has been found that some fillers may be favorable to one property of the resin composition but detrimental to another property of the resin composition. In addition, the addition of fillers such as rubber and plasticizer may adversely affect the thermal stability of the resin composition.

The filler suitable for the PLA resin composition of some embodiments of the present disclosure comprises an inorganic filler (e.g., glass fibers or crystalline silicon), a carbonaceous filler (e.g., in the form of carbonaceous fibers or particles such as carbon fibers or carbon black), or any combination of two or more thereof. In some embodiments, the filler comprises carbon fibers, carbon black, or both. In other embodiments, the filler comprises carbon fibers. It has been found that adding such filler into the PLA resin composition of some embodiments of the present disclosure can greatly improve mechanical properties, especially the impact strength, and further increase the HDT, of the PLA. Due to the synergetic effects of the nucleating agent and the filler, a resulting PLA product has superior mechanical properties and thermal properties, including a high HDT (measured according to ASTM D-648 under a load of 264 psi) of about 134° C. or higher and an impact strength of about 1.5 kg-cm/cm or higher.

In some embodiments, the filler, such as carbon fibers, carbon black, or crystalline silicon, may also decrease the surface resistivity of the PLA resin composition, so that the resulting PLA product may be antistatic.

The filler having various suitable lengths and/or diameters can be used. In some embodiments, a length (e.g., an average length) of the filler, such as carbon fibers, is from about 0.01 mm to about 800 mm, for example, about 0.01 mm, about 1 mm, about 10 mm, about 50 mm, about 100 mm, about 200 mm, about 300 mm, about 400 mm, about 500 mm, about 600 mm, about 700 mm, or about 800 mm. In some embodiment, a diameter (e.g., an average diameter) of the filler, such as carbon black or carbon fibers, is from about 0.01 μm to about 100 μm, for example, about 0.01 μm, about 1 μm, about 10 μm, about 20 μm, about 30 μm, about 40 μm, about 50 μm, about 60 μm, about 70 μm, about 80 μm, about 90 μm, or about 100 μm.

The filler can be added in varying suitable amounts in the PLA resin composition as long as it can produce the synergetic effects together with the nucleating agent. In some embodiments, the filler is added to the PLA resin composition of some embodiments of the present disclosure in an amount of about 3 to about 70 parts by weight based on about 100 parts by weight of the PLA resin, for example, about 3, about 5, about 10, about 15, about 20, about 25, about 30, about 35, about 40, about 45, about 50, about 55, about 60, about 65, or about 70 parts by weight based on about 100 parts by weight of the PLA resin. In some embodiments, the filler is added to the PLA resin composition in an amount of about 3 to about 50 parts, about 5 to about 50 parts, or about 5 to about 30 parts by weight based on about 100 parts by weight of the PLA resin. If the content of the filler is insufficient, the effect of the filler may not be significant. If the content of the filler is too high, it may cause poor dispersion of the filler, and even agglomeration of the filler, both of which can reduce the conductivity of the PLA resin and affect the antistatic properties of the PLA resin.

### [Coupling Agent]

In the PLA resin composition of some embodiments of the present disclosure, the PLA is an organic material, whereas the filler is an inorganic material. Unlike organic materials which may form bonding between each other by functional groups thereof, an inorganic material usually does not form strong bonding with an organic material, which may lead to poor compatibility and adhesion between the PLA and the inorganic filler. To address this issue, a coupling agent may be employed to modify the surface of the inorganic filler and bond the inorganic filler to the organic material via its dual reactivity. A coupling agent also may be employed for an organic filler to further enhance compatibility and adhesion between the PLA and the organic filler. In some embodiments, a filler is bonded (e.g., covalently bonded) to the PLA via a coupling agent.

The coupling agent may be a silane coupling agent, a titanate coupling agent or a combination thereof. Various suitable silane coupling agents and titanate coupling agents can be selected. Examples of suitable silane coupling agents for some embodiments of the present disclosure include, but are not limited to, trimethoxysilane, triethoxysilane, or a combination thereof. According to some embodiments of the present disclosure, the silane coupling agent may be 3-acryloxypropyl trimethoxysilane, 2-(3,4-epoxycyclohexyl) ethyltrimethoxysilane or a combination thereof. Examples of suitable titanate coupling agents for some embodiments of the present disclosure include, but are not limited to, titanium di(cumylphenylate) oxyacetate, di(dioctylphosphato) ethylene titanate, or a combination thereof.

The coupling agent can be added in varying suitable amounts in the PLA resin composition, and can be adjusted depending on the content of the filler. In some embodiments, the coupling agent may be added in the PLA resin composition in an amount of about 0.001 to about 5 parts by weight based on about 100 parts by weight of the PLA resin, for example, about 0.001, about 0.005, about 0.01, about 0.05, about 0.1, about 0.5, about 1, about 2, about 3, about 4, or about 5 parts by weight based on about 100 parts by weight of the PLA resin.

### [Polylactic Acid Resin Composition]

The PLA resin composition of some embodiments of the present disclosure can be prepared by various suitable methods. In some embodiments, the PLA resin composition is prepared by: (1) mixing a PLA resin with a nucleating agent to form a first mixture, (2) mixing a filler and a coupling agent to form a second mixture, and (3) adding the second mixture to the first mixture (or otherwise combining the first mixture and the second mixture) to prepare the PLA resin composition.

The PLA resin composition can be further processed into end products, such as a cover for an electronic product (e.g., mobile phone or computer), food containers or trays, or trays for industrial components. In some embodiments, the PLA resin composition can be kneaded by a twin screw extruder and then injected to form a tray with an injection molding machine at a temperature range of from about 150° C. to about 200° C. The tray may be further baked in order to release stress and stabilize a tray size.

The product made by the PLA resin composition of some embodiments of the present disclosure is biodegradable, such that the product can be decomposed in a natural environment, for example, by microorganism. In some embodiments, the PLA resin composition may have a degree of decomposition of about 70 wt. % or higher in about 90 days in a natural environment.

In some embodiments, the PLA resin composition is processed into a tray. In further embodiments, the tray has an impact strength of about 1.5 kg-cm/cm or higher (e.g., about 1.55 kg-cm/cm or higher, about 1.6 kg-cm/cm or higher, about 1.65 kg-cm/cm or higher, about 1.7 kg-cm/cm or higher, about 1.75 kg-cm/cm or higher, about 1.8 kg-cm/cm or higher, about 1.85 kg-cm/cm or higher, or about 1.9 kg-cm/cm or higher, and up to about 1.95 kg-cm/cm or higher), a HDT of about 125° C. or higher (e.g., about 130° C. or higher, about 135° C. or higher, about 140° C. or higher, about 145° C. or higher, or about 150° C. or higher, and up to about 155° C. or higher), and a surface resistivity of about 10¹² ohms/sq or smaller (e.g., about 10¹¹ ohms/sq or smaller, about 10¹⁰ ohms/sq or smaller, about 10⁹ ohms/sq or smaller, about 10⁸ ohms/sq or smaller, about 10⁷ ohms/sq or smaller, about 10⁶ ohms/sq or smaller, about 10⁵ ohms/sq or smaller, or about 10⁴ ohms/sq or smaller, and down to about 10³ ohms/sq or smaller). The tray is applicable to electronics industry, such as an IC tray, which specifies a high HDT, a high impact strength and a low surface resistivity (e.g., a HDT of about 125° C. or higher, an impact strength of about 1.5 kg-cm/cm or higher and a surface resistivity of about 10¹² ohms/sq or smaller).

In some embodiments, the PLA resin composition is processed into a biodegradable molded article. In further embodiments, the biodegradable molded article has a degradable degree of about 70 wt. % or higher after about 90 days in a natural environment. In further embodiments, the biodegradable molded article has an impact strength of about 1.5 kg-cm/cm or higher (e.g., about 1.55 kg-cm/cm or higher, about 1.6 kg-cm/cm or higher, about 1.65 kg-cm/cm or higher, about 1.7 kg-cm/cm or higher, about 1.75 kg-cm/cm or higher, about 1.8 kg-cm/cm or higher, about 1.85 kg-cm/cm or higher, or about 1.9 kg-cm/cm or higher, and up to about 1.95 kg-cm/cm or higher), a HDT of about 125° C. or higher (e.g., about 130° C. or higher, about 135° C. or higher, about 140° C. or higher, about 145° C. or higher, or about 150° C. or higher, and up to about 155° C. or higher), and a surface resistivity of about 10¹² ohms/sq or smaller (e.g., about 10¹¹ ohms/sq or smaller, about 10¹⁰ ohms/sq or smaller, about 10⁹ ohms/sq or smaller, about 10⁸ ohms/sq or smaller, about 10⁷ ohms/sq or smaller, about 10⁶ ohms/sq or smaller, about 10⁵ ohms/sq or smaller, or about 10⁴ ohms/sq or smaller, and down to about 10³ ohms/sq or smaller). The biodegradable molded article is applicable to electronics industry, which specifies a high HDT, a high impact strength and a low surface resistivity (e.g., a HDT of about 125° C. or higher, an impact strength of about 1.5 kg-cm/cm or higher and a surface resistivity of about 10¹² ohms/sq or smaller).

### EXAMPLES

Some embodiments of the present disclosure will now be further explained with reference to the following working examples and comparative examples; however, these examples do not restrict the scope of embodiments of this disclosure. In the examples, polylactic acid (NatureWorks® 4032D), L-alanine (Merck co.), carbon fibers (TAIRYFIL® CS-2516), carbon black (CABOT® XC-72), glass fibers (TAIWANGLASS GROUP 188), and coupling agent (ShinEtsu KBM-503) were used. The relative amounts of each component are illustrated in Tables 1 and 3.

PLA was uniformly mixed with L-alanine to prepare a first mixture. Components (c) and (d) were mixed to prepare a second mixture. The second mixture was added to the first mixture to prepare a PLA resin composition. The PLA resin composition was kneaded by a twin screw extruder at a temperature range of from about 160° C. to about 195° C. and then injected to form a tray with an injection molding machine at a temperature range of from about 150° C. to about 200° C.

The properties of each tray were tested according to the ASTM methods depicted in Tables 2 and 4 and the results were recorded in Tables 2 and 4.

TABLE 1

| | | | | | Compar. | Compar. |
|---|---|---|---|---|---|---|
| | | Ex. 1 | Ex. 2 | Ex. 3 | Ex. 4 | Ex. 5 |
| (a) | polylactic acid | 100 | 100 | 100 | 100 | 100 |
| (b) | L-alanine | 1.5 | 1.5 | 1.5 | 1.5 | — |
| (c1) | carbon fiber (CF) | 30 | 15 | — | — | — |
| (c2) | carbon black (CB) | — | 5 | — | — | — |
| (c3) | glass fiber (GF) | — | — | 15 | — | — |
| (d) | coupling agent | 3 | 1.2 | 1.5 | — | — |

| | | | | | | Compar. | Compar. |
|---|---|---|---|---|---|---|---|
| Method | Property | Unit | Ex. 1 | Ex. 2 | Ex. 3 | Ex. 4 | Ex. 5 |
| ASTM | Special | — | 1.38 | 1.35 | 1.39 | 1.37 | 1.39 |
| D-792 | Gravity | | | | | | |
| ASTM | Elongation | % | 0.43 | 0.86 | 0.3 | 5 | 8.2 |
| D-638 | | | | | | | |
| ASTM | Tensile | kg/cm² | 891 | 830 | 407 | 305 | 225 |
| D-638 | Strength | | | | | | |
| ASTM | Impact | kg-cm/ | 1.88 | 1.95 | 1.91 | 1.35 | 1.21 |
| D-256 | Strength | cm | | | | | |
| ASTM | Flexural | kg/cm² | 1486 | 1317 | 748 | 603 | 468 |
| D-638 | Strength | | | | | | |
| ASTM | Flexural | kg/cm² | 168200 | 108200 | 62100 | 34700 | 26500 |
| D-638 | Modulus | | | | | | |
| ASTM | Surface | ohms/sq | 1.5E+3 | 4.7E+4 | 2E+12 | 3.5E+12 | 3.5E+12 |
| D-257 | Resistivity | | | | | | |
| ASTM | HDT | ° C. | 154.6 | 137.9 | 134 | 130 | 52 |
| D-648 | | | | | | | |

In view of Comparative Examples 4 and 5, the use of a nucleating agent can increase the HDT of the PLA product from about 52° C. to about 130° C. With the support from the filler, Examples 1 to 3 have a HDT higher than about 130° C. (here, about 134° C. or higher) and exhibit much improved mechanical properties (tensile strength, impact strength, flexural strength and flexural modulus) than Comparative Examples 4 and 5. Notably, the impact strength of Examples 1 to 3 is from about 1.88 to about 1.95 kg-cm/cm, much higher than that (about 1.35 and about 1.21 kg-cm/cm) of Comparative Examples 4 and 5.

The surface resistivity of Examples 1 and 2 is about 1.5×10³ and 4.7×10⁴ ohms/sq, significantly lower than that of Example 3 and Comparative Examples 4 and 5, which shows that the use of carbon fiber can further improve the antistatic properties of the PLA tray.

TABLE 3

| Ingredient | | Ex. 1 | Ex. 6 | Ex. 7 |
|---|---|---|---|---|
| (a) | polylactic acid | 100 | 100 | 100 |
| (b) | L-alanine | 1.5 | 1.5 | 1.5 |
| (c) | carbon fiber (CF) | 30 | 10 | 5 |
| (d) | coupling agent | 3 | 1.5 | 1.5 |

TABLE 4

| Method | Property | Unit | Ex. 1 | Ex. 6 | Ex. 7 |
|---|---|---|---|---|---|
| ASTM | Special | — | 1.38 | 1.36 | 1.37 |
| D-792 | Gravity | | | | |
| ASTM | Elongation | % | 0.43 | 0.91 | 1.34 |
| D-638 | | | | | |
| ASTM | Tensile | kg/cm² | 891 | 824 | 584 |
| D-638 | Strength | | | | |
| ASTM | Impact | kg-cm/cm | 1.88 | 1.81 | 1.58 |
| D-256 | Strength | | | | |
| ASTM | Flexural | kg/cm² | 1486 | 1296 | 939 |
| D-638 | Strength | | | | |
| ASTM | Flexural | kg/cm² | 168200 | 111000 | 73200 |
| D-638 | Modulus | | | | |
| ASTM | Surface | ohms/sq | 1.5E+3 | 3.5E+6 | 8.5E+8 |
| D-257 | Resistivity | | | | |
| ASTM | HDT | ° C. | 154.6 | 139 | 135 |
| D-648 | | | | | |

Examples 1, 6 and 7 have the same composition except that the amount of inorganic filler is about 30 parts by weight, about 10 parts by weight, and about 5 parts by weight, respectively, based on about 100 parts by weight of the PLA resin. Example 7 using about 5 parts by weight of filler also achieves the effects of enhanced mechanical properties, HDT and reduced surface resistivity similar to Examples 1 to 3. When the amount of filler is about 10 parts by weight or more (Examples 1 and 6), the properties of the PLA tray can be further improved, such as having a HDT higher than about 135° C. and impact strength of higher than about 1.8 kg-cm/cm. Overall, all of the PLA trays produced from Examples 1 to 3 and 6 and 7 possess appropriate HDT, mechanic properties, and reduced surface resistivity, which are thus suitable to be utilized in electronics industry, such as an IC tray.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

As used herein, the singular terms “a,” “an,” and “the” may include plural referents unless the context clearly dictates otherwise.

Amounts, ratios, and other numerical values are sometimes presented herein in a range format. It can be understood that such range formats are used for convenience and brevity, and should be understood flexibly to include not only numerical values explicitly specified as limits of a range, but also all individual numerical values or sub-ranges encompassed within that range as if each numerical value and sub-range is explicitly specified.

While the present disclosure has been described and illustrated with reference to specific embodiments thereof, these descriptions and illustrations do not limit the present disclosure. It can be clearly understood by those skilled in the art that various changes may be made, and equivalent elements may be substituted within the embodiments without departing from the true spirit and scope of the present disclosure as defined by the appended claims. The illustrations may not necessarily be drawn to scale. There may be distinctions between the artistic renditions in the present disclosure and the actual apparatus, due to variables in manufacturing processes and such. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it can be understood that these operations may be combined, sub-divided, or re-ordered to form an equivalent method without departing from the teachings of the present disclosure. Therefore, unless specifically indicated herein, the order and grouping of the operations are not limitations of the present disclosure.

What is claimed is:

1. A polylactic acid resin composition, comprising:
100 parts by weight of a polylactic acid resin;
0.001 to 3 parts by weight of a nucleating agent based on 100 parts by weight of the polylactic acid resin; and
3 to 50 parts by weight of a filler based on 100 parts by weight of the polylactic acid resin.

2. The polylactic acid resin composition according to claim 1, wherein the nucleating agent comprises a metal carbonate, an ester derivative of citric acid, a metal silicate, an amino acid, a poly(amino acid), a heterocyclic organic compound, a metal oxide, or a combination of two or more thereof.

3. The polylactic acid resin composition according to claim 1, wherein an amount of the filler is 5 to 30 parts by weight based on 100 parts by weight of the polylactic acid resin.

4. The polylactic acid resin composition according to claim 1, wherein the filler is an inorganic filler.

5. The polylactic acid resin composition according to claim 1, wherein the filler comprises carbon fibers, carbon black, glass fibers, or a combination of two or more thereof.

6. The polylactic acid resin composition according to claim 5, wherein the filler comprises carbon fibers, carbon black, or a combination thereof.

7. The polylactic acid resin composition according to claim 5, wherein the filler comprises carbon fibers.

8. The polylactic acid resin composition according to claim 1, wherein the filler has a diameter from 0.01 μm to 100 μm.

9. The polylactic acid resin composition according to claim 1, further comprising a coupling agent in an amount of 0.001 to 5 parts by weight based on 100 parts by weight of the polylactic acid resin.

10. The polylactic acid resin composition according to claim 9, wherein the coupling agent comprises a silane coupling agent, a titanate coupling agent, or a combination thereof.

11. The polylactic acid resin composition according to claim 10, wherein the coupling agent comprises 3-acryloxypropyl trimethoxysilane, 2-(3,4-epoxycyclohexyl) ethyltrimethoxysilane, or a combination thereof.

12. A tray for electronics, comprising:
100 parts by weight of a polylactic acid resin;
0.001 to 3 parts by weight of a nucleating agent based on 100 parts by weight of the polylactic acid resin; and
3 to 50 parts by weight of a filler based on 100 parts by weight of the polylactic acid resin.

13. The tray according to claim 12, further comprising a coupling agent in an amount of 0.001 to 5 parts by weight based on 100 parts by weight of the polylactic acid resin.

14. The tray according to claim 12, wherein the filler comprises carbon fibers, carbon black, glass fibers, or a combination of two or more thereof.

15. The tray according to claim 12, having an impact strength of 1.5 kg-cm/cm or higher measured according to ASTM D-256, a surface resistivity of 10¹² ohm/sq or smaller measured according to ASTM D-257, and a heat deflection temperature of 125° C. or higher measured according to ASTM D-648 under a load of 264 psi.

16. A biodegradable molded article, comprising:
100 parts by weight of a polylactic acid resin;
0.001 to 3 parts by weight of a nucleating agent based on 100 parts by weight of the polylactic acid resin; and
3 to 50 parts by weight of a filler based on 100 parts by weight of the polylactic acid resin.

17. The biodegradable molded article according to claim 16, having a degradable degree of at least 70 wt. % after 90 days.

18. The biodegradable molded article according to claim 16, wherein the molded article is a tray for electronics.

19. The biodegradable molded article according to claim 16, wherein the filler comprises carbon fibers, carbon black, glass fibers, or a combination of two or more thereof.

20. The biodegradable molded article according to claim 16, having an impact strength of 1.5 kg-cm/cm or higher measured according to ASTM D-256, a surface resistivity of 10¹² ohm/sq or smaller measured according to ASTM D-257, and a heat deflection temperature of 125° C. or higher measured according to ASTM D-648 under a load of 264 psi.
